(19) United States
(12) Patent Application Publication
(10) Pub. No.: US 2024/0212924 A1
(43) Pub. Date: Jun. 27, 2024

(54) COIL DEVICE

(71) Applicant: TDK CORPORATION, Tokyo (JP)

(72) Inventors: Riku UMEKI, Tokyo (JP); Satoshi SUGIMOTO, Tokyo (JP)

(73) Assignee: TDK CORPORATION, Tokyo (JP)

(21) Appl. No.: 18/543,094

(22) Filed: Dec. 18, 2023

(30) Foreign Application Priority Data
Dec. 21, 2022 (JP) 2022-204695

(51) Int. Cl. H01F 27/30; H01F 27/26; H01F 27/28; H01F 27/29; H05K 1/18

(52) U.S. Cl. CPC H01F 27/306; H01F 27/263; H01F 27/2852; H01F 27/292; H05K 1/181; H05K 2201/1003

(57) ABSTRACT

A coil device comprises a core and a coil including a folded metal plate member having a pair of main surfaces extending in a direction perpendicular to a bottom surface of the core. The coil includes a first conductor, a second conductor, and a third conductor. The first conductor includes a first main portion, which is disposed inside the core, and a first terminal portion, which is connected to the first main portion and partly protrudes below the bottom surface. The second conductor includes a second main portion, which is disposed inside the core and farther from the bottom surface than the first main portion, and a second terminal portion, which is connected to the second main portion and partly protrudes below the bottom surface. The third conductor includes a joint portion connecting the first conductor and the second conductor and a locating portion partly protruding below the bottom surface.

### TECHNICAL FIELD

The present disclosure relates to a coil device used as, for example, an inductor.

### BACKGROUND

As a power inductor with reduced failure risks, known is a coil device in which a plate-shaped conductor constitutes a winding portion and a terminal portion (Patent Document 1). Such a coil device requires a large mounting area when being mounted on a circuit board (e.g., PCB), which is an obstructive factor of size reduction of a product including the coil device.

Patent Document 1: JP Patent Application Laid Open No. 2000-68129

### SUMMARY

The present disclosure is achieved in view of such circumstances. It is an object of the disclosure to provide a coil device that allows products to be made smaller.

To achieve the above object, a coil device according to the present disclosure is a coil device comprising:
a core; and
a coil including a folded metal plate member having a pair of main surfaces extending in a direction perpendicular to a bottom surface of the core;
wherein
the coil includes a first conductor, a second conductor, and a third conductor;
the first conductor includes a first main portion and a first terminal portion;
the first main portion is disposed inside the core;
the first terminal portion is connected to the first main portion and partly protrudes below the bottom surface;
the second conductor includes a second main portion and a second terminal portion;
the second main portion is disposed inside the core and farther from the bottom surface than the first main portion;
the second terminal portion is connected to the second main portion and partly protrudes below the bottom surface;
the third conductor includes a joint portion and a locating portion;
the joint portion connects the first conductor and the second conductor; and
the locating portion partly protrudes below the bottom surface.

Such a structure enables the coil device to be mounted on a circuit board or the like of a product including the coil device, with the bottom surface having a small area facing the circuit board or the like. Thus, the mounting area can be reduced, which can downsize the product.

Moreover, the coil device has a raised bottom structure, which can provide a space for mounting another electronic device or the like between the bottom surface of the core and the circuit board or the like when the coil device is mounted thereon. Thus, the product including the coil device can be downsized.

Such a coil can be molded to ensure having desired inductance. Moreover, such a coil device is applicable for use involving a large current, with reduced failure risks.

The first main portion may be disposed so as to at least partly overlap the second main portion, viewed from the direction perpendicular to the bottom surface.

Such a structure enables the bottom surface of the core to have a small area, which can reduce the mounting area.

The first terminal portion and the second terminal portion may be disposed over an outer surface of the core at one side; and the locating portion may be disposed over the outer surface of the core at an other side.

Such a structure can ensure that one turn of winding is provided, which stabilizes mounting of the coil device on the circuit board or the like.

The joint portion may comprise a first connecting end portion having at least one of the main surfaces being curved from the first main portion to run along an outer surface of the core, a second connecting end portion having at least one of the main surfaces being curved from the second main portion to run along the outer surface, and a connecting portion connecting the first connecting end portion and the second connecting end portion;
the connecting portion may comprise a middle portion extending in a direction parallel to the bottom surface of the core;
the connecting portion may have a first space between the middle portion and the first connecting end portion and a second space between the middle portion and the second connecting end portion; and
the first space and the second space may have a width not smaller than a thickness of the coil.

Such a structure enables the coil to be easily molded by folding the metal plate member.

The core may comprise a first section and a second section opposing each other in the direction parallel to the bottom surface of the core; and
the first main portion and the second main portion may be interposed between the first section and the second section.

Combining such separately molded sections of the core can make it easy to manufacture the coil device.

The first section may comprise a base portion having a substantially flat shape and a leg portion protruding from the base portion towards the second section; and
an end surface of the leg portion may be disposed so that a gap is provided between the end surface and the second section.

Providing the gap enables leakage from the coil device to be adjusted.

The first section may be connected to the second section using an adhesive member.

The core can be easily molded by connecting the first section and the second section using the adhesive member. With the adhesive member, the gap between the sections can be adjusted.

A length of the leg portion protruding from the base portion may be larger than the thickness of the coil in the direction parallel to the bottom surface.

When the gap is provided between the sections, such a structure enables the gap not to be disposed at lateral sides of the first main portion and the second main portion to more efficiently adjust leakage.

The first terminal portion may be disposed over an outer surface of the first section at one side; and
the second terminal portion may be disposed over an outer surface of the second section at the one side and next to the first terminal portion.

Such a structure enables the coil device to have increased inductance.

The first main portion and the second main portion may have different widths.

Changing the widths of the main portions can also adjust inductance of the coil device.

### BRIEF DESCRIPTION OF THE DRAWING(S)

FIG. 1 is a perspective view of a coil device according to an embodiment.

FIG. 2 is a side elevational view of the coil device illustrated in FIG. 1 viewed from one side.

FIG. 3 is a side elevational view of the coil device illustrated in FIG. 1 viewed from the other side.

FIG. 4 is a perspective view of a coil of the coil device illustrated in FIG. 1.

FIG. 5 is a schematic view of the coil illustrated in FIG. 4 in a manufacturing step.

FIG. 6 is a perspective view of a core of the coil device illustrated in FIG. 1.

FIG. 7 is a sectional view along line VII-VII shown in FIG. 1.

FIG. 8 is a side elevational view of the coil device illustrated in FIG. 1 being mounted on a circuit board.

FIG. 9 is a perspective view of a coil device according to another embodiment.

FIG. 10 is a perspective view of a core of the coil device illustrated in FIG. 9.

FIG. 11 is a sectional view along line XI-XI shown in FIG. 9.

FIG. 12 is a perspective view of a coil device according to still another embodiment.

FIG. 13 is a sectional view of the coil device illustrated in FIG. 12.

### DETAILED DESCRIPTION

Embodiments of the present disclosure are described with reference to the drawings. Although the embodiments are described with reference to the drawings as necessary, the illustrations are only schematically and exemplarily provided for understanding of the embodiments, and the appearance, dimensional ratios, etc. may be different from the actual ones. The present disclosure is specifically described below based on the embodiments but is not limited to these embodiments.

### First Embodiment

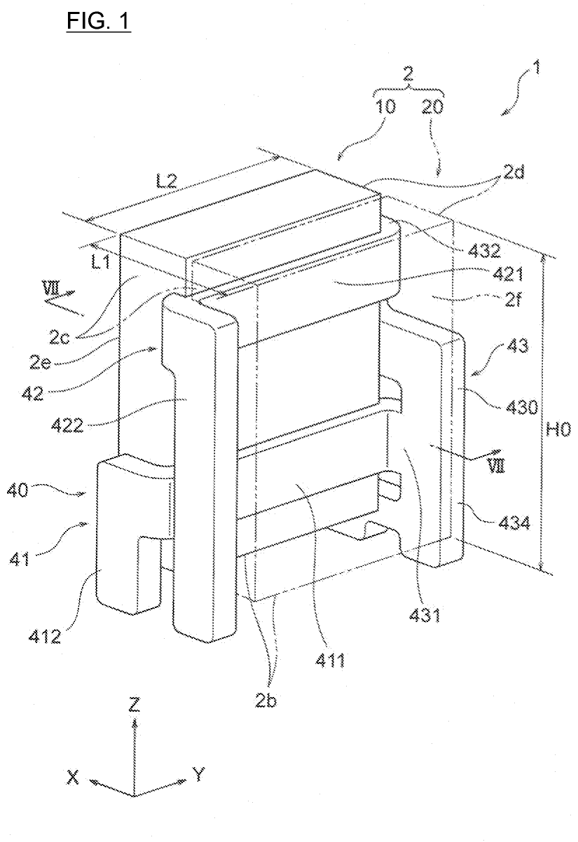

A coil device 1 according to the present embodiment illustrated in FIG. 1 is used as, for example, an inductor for a power supply.

As illustrated in FIG. 1, the coil device 1 includes a core 2 and a coil 40. The core 2 includes a top surface 2a, a bottom surface 2b, outer surfaces 2c and 2d, and base surfaces 2e and 2f and has a substantially rectangular parallelepiped shape having a height H0 in the Z-axis direction, a length L1 in the X-axis direction, and a width L2 in the Y-axis direction. However, the shape may be any other shapes. The top surface 2a and the bottom surface 2b are opposite each other in the Z-axis direction. The outer surfaces 2c and 2d are opposite each other in the Y-axis direction. The base surfaces 2eand 2f are opposite each other in the X-axis direction. Note that, in the drawings, the X-axis, Y-axis, and Z-axis directions are mutually orthogonal.

The core 2 May have any dimensions. The length L1 is, for example, 2.0 to 8.0 mm. The width L2 is, for example, 7.0 to 15.0 mm. The height H0 is, for example, 7.0 to 20.0 mm.

As illustrated in FIG. 1, the core 2 includes a first section 10 and a second section 20 opposing each other in the X-axis direction. In this exemplary embodiment, the first section 10 and the second section 20 combine to constitute the top surface 2a, the bottom surface 2b, the outer surfaces 2c and 2d, and the base surfaces 2e and 2f of the core 2. Note that, in the specification, the direction towards the bottom surface 2b along the Z-axis may be referred to as a downward direction, and the direction towards the top surface 2a along the Z-axis may be referred to as an upward direction. Also in the specification, the direction towards the base surfaces 2e and 2f may be referred to as an outward direction, and the direction away from the base surfaces 2e and 2f may be referred to as an inward direction.

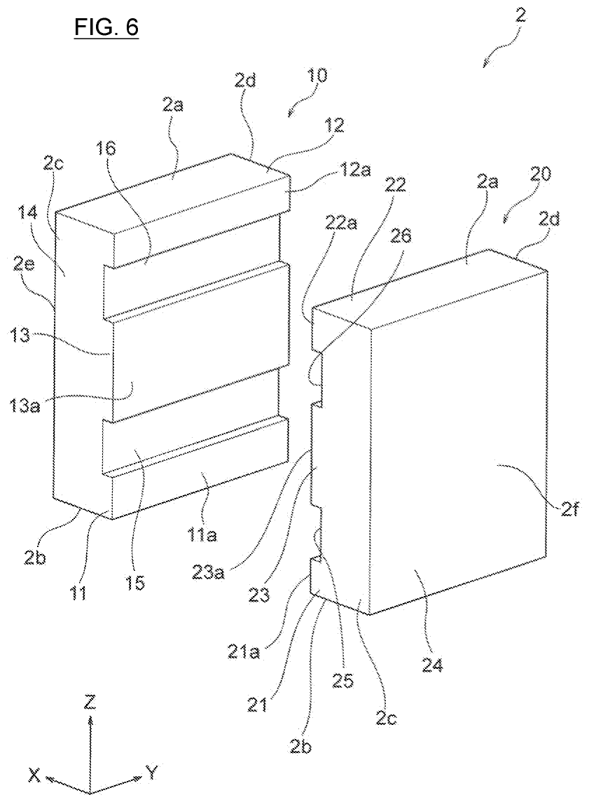

The first section 10 and the second section 20 are disposed to oppose each other in the X-axis direction. The first section 10 and the second section 20 May be joined using, for example, an adhesive member 3. The first section 10 and the second section 20 May be produced by molding and sintering a magnetic powder containing ferrites or metal magnetic material. Examples of ferrites are not limited and include Ni—Zn based ferrites and Mn—Zn based ferrites. Examples of metal magnetic material are not limited and include Fe—Ni alloys, Fe—Si alloys, Fe—Si—Cr alloys, Fe—Co alloys, and Fe—Si—Al alloys. As illustrated in FIG. 6, the first section 10 and the second section 20 have a so-called E-shape but may have any other shapes. As illustrated in FIG. 6, the first section 10 includes a base portion 14 having a substantially flat shape (substantially rectangular parallelepiped shape) and leg portions protruding from the base portion 14. The leg portions include a first outer leg portion 11, a second outer leg portion 12, and a middle leg portion 13. The middle leg portion 13 is disposed between the first outer leg portion 11 and the second outer leg portion 12. An outer surface of the base portion 14 in the X-axis direction constitutes the base surface 2e.

As illustrated in FIG. 6, the first outer leg portion 11, the second outer leg portion 12, and the middle leg portion 13 protrude inwards from the base portion 14 along the X-axis. Between the first outer leg portion 11 and the middle leg portion 13 is a first recess 15. In the first recess 15, a first conductor 41 of the coil 40 (described later) is partly disposed. Between the second outer leg portion 12 and the middle leg portion 13 is a second recess 16. In the second recess 16, a second conductor 42 of the coil 40 (described later) is partly disposed.

Similarly to the first section 10, the second section 20 includes a base portion 24, a first outer leg portion 21, a second outer leg portion 22, and a middle leg portion 23. The middle leg portion 23 is disposed between the first outer leg portion 21 and the second outer leg portion 22. An outer surface of the base portion 24 in the X-axis direction constitutes the base surface 2f. Between the first outer leg portion 21 and the middle leg portion 23 is a first recess 25. Between the second outer leg portion 22 and the middle leg portion 23 is a second recess 26. Although the first section 10 and the second section 20 have symmetrical shapes opposing each other in the X-axis direction in the present embodiment, the shapes are not limited to these shapes and may have different dimensions or the like. The description of the first section 10 applies also to the second section 20.

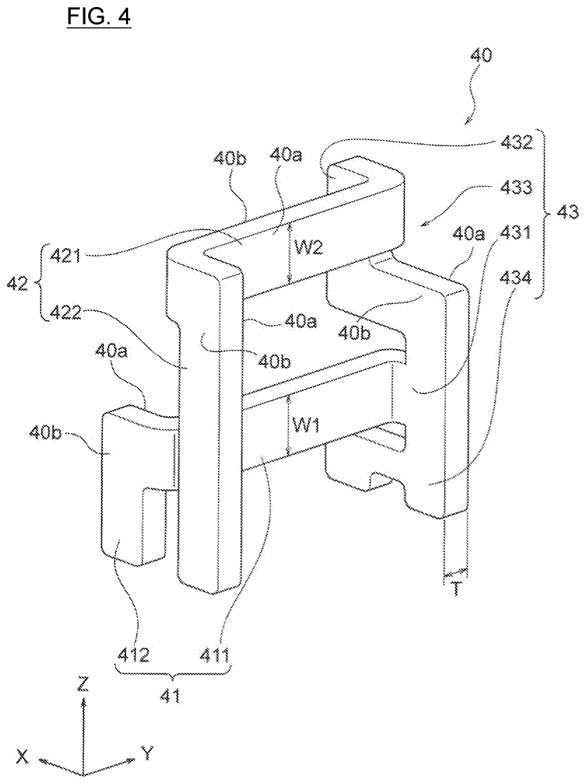

As illustrated in FIG. 4, the coil 40 includes a folded metal plate member having a thickness T and having a pair of main surfaces 40a and 40b extending in the Z-axis direction. The metal plate member constituting the coil 40 is not limited, and good conductors, such as copper, copper alloys, silver, and gold, may be used. The thickness T is not limited and may be, for example, 0.2 to 3 mm. Note that, the main surfaces are surfaces perpendicular to the thickness direction. The main surfaces 40a and 40b of the coil 40 extend in the Z-axis direction in the first and second conductors (described later). However, the coil 40 May include other portions in which the main surfaces extend in the X-axis direction or the Y-axis direction.

As illustrated in FIG. 4, the coil 40 includes the first conductor 41, the second conductor 42, and a third conductor 43. As illustrated in FIG. 1, the first conductor 41 includes a first main portion 411, which is disposed inside the core 2, and a first terminal portion 412, which is connected to the first main portion 411 and partly protrudes downwards below the bottom surface 2b.

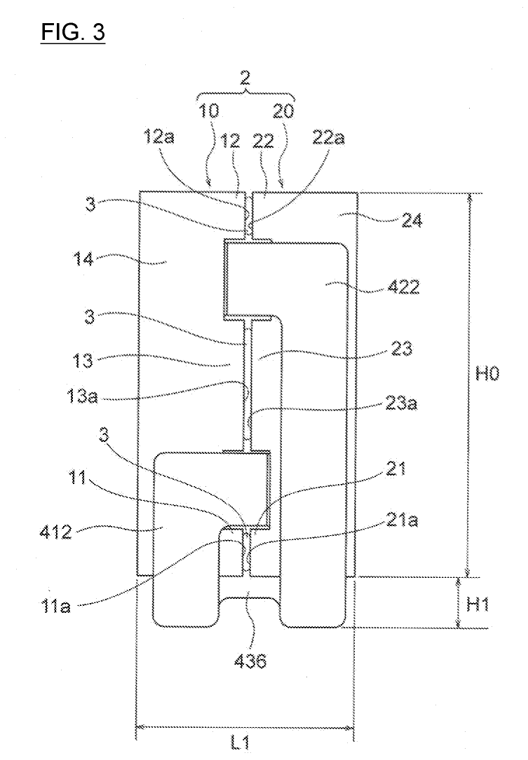

The first main portion 411 is disposed between the first section 10 and the second section 20. As illustrated in FIG. 3, the first terminal portion 412 is disposed over the outer surface 2c of the first section 10.

As illustrated in FIG. 1, the second conductor 42 includes a second main portion 421, which is disposed inside the core 2 and farther from the bottom surface 2b than the first main portion 411, and a second terminal portion 422, which is connected to the second main portion 421 and partly protrudes below the bottom surface 2b.

The second main portion 421 is disposed between the first section 10 and the second section 20. As illustrated in FIG. 3, the second terminal portion 422 is disposed over the outer surface 2c of the second section 20 and next to the first terminal portion 412. The bottom surface 2b of the core 2 is disposed so as to be at a level that is higher by a height H1 from the level of lower ends of the first terminal portion 412 and the second terminal portion 422 in the Z-axis direction.

As illustrated in FIG. 4, a width W1 of the first main portion 411 in the Z-axis direction and a width W2 of the second main portion 421 in the Z-axis direction are not limited. The width W1 of the first main portion 411 and the width W2 of the second main portion 421 may be the same or may be different.

As illustrated in FIG. 1, the third conductor 43 includes a joint portion 430, which connects the first conductor 41 and the second conductor 42, and a locating portion 434, which partly protrudes below the bottom surface 2b. The locating portion 434 is disposed over the outer surface 2d of the core 2.

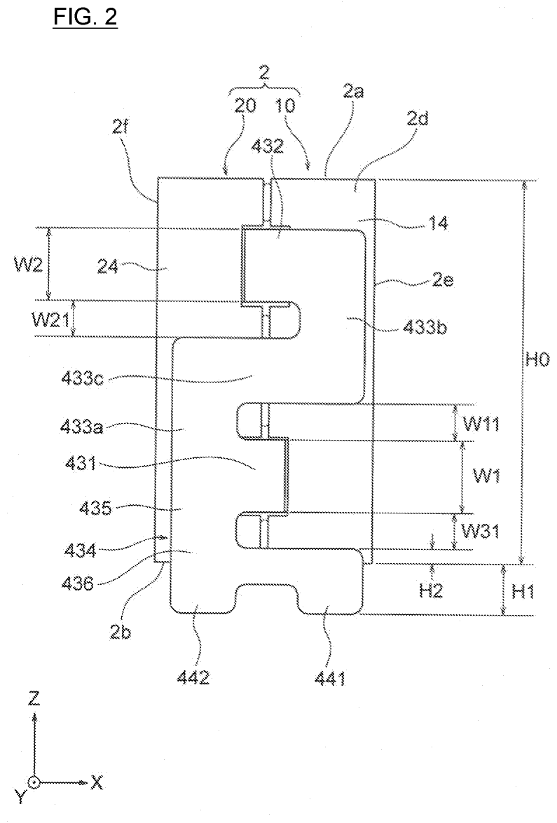

As illustrated in FIG. 2, the joint portion 430 includes a first connecting end portion 431 having the main surface 40a being curved from the first main portion 411 to run along the outer surface 2d of the second section 20; a second connecting end portion 432 having the main surface 40a being curved from the second main portion 421 to run along the outer surface 2d of the first section 10; and a connecting portion 433 connecting the first connecting end portion 431 and the second connecting end portion 432 in a crank shape along the outer surface 2d of the core 2.

As illustrated in FIG. 2, the connecting portion 433 includes a first portion 433a, a second portion 433b, and a middle portion 433c. The first portion 433a extends over the outer surface 2d of the second section 20 along the Z-axis to connect the first connecting end portion 431 and the middle portion 433c. The second portion 433b extends over the outer surface 2d of the first section 10 along the Z-axis to connect the second connecting end portion 432 and the middle portion 433c. The middle portion 433c extends in the X-axis direction and is connected to the first portion 433a at one end and to the second portion 433b at the other end in the X-axis direction. The middle portion 433c is disposed between the first connecting end portion 431 and the second connecting end portion 432.

As illustrated in FIG. 2, the connecting portion 433 has a first space having a predetermined width W11 in the Z-axis direction between the middle portion 433c and the first connecting end portion 431. Likewise, the connecting portion 433 has a second space having a predetermined width W21 in the Z-axis direction between the middle portion 433c and the second connecting end portion 432. The width W11 of the first space and the width W21 of the second space are not smaller than the thickness T of the metal plate member constituting the coil.

As illustrated in FIG. 2, the locating portion 434 includes a supporting portion 435 and a reinforcing portion 436. The supporting portion 435 connects to the first connecting end portion 431 and extends along the Z-axis in a direction opposite the first portion 433a of the connecting portion 433.

The reinforcing portion 436 connects to the supporting portion 435 and extends in the X-axis direction. Between the first connecting end portion 431 and the reinforcing portion 436 is a third space having a predetermined width W31 in the Z-axis direction.

The width W31 of the third space is not smaller than the thickness T of the metal plate member constituting the coil.

An upper part of the reinforcing portion 436 in the Z-axis direction is disposed along the outer surface 2d at a level that is higher by a height H2 from the level of the bottom surface 2b of the core 2. A lower part of the reinforcing portion 436 in the Z-axis direction protrudes below the bottom surface 2b of the core 2. The lower part of the reinforcing portion 436 in the Z-axis direction is provided with protrusions 441 and 442. The bottom surface 2b of the core 2 is disposed so as to be at a level that is higher by the height H1 from the level of lower ends of the protrusions 441 and 442 in the Z-axis direction.

The heights H1 and H2 are not limited and may be determined in view of, for example, mounting strength and stability. For example, the height H1 may be 5% to 15% of the height H0 of the core 2. For example, the height H2 may be 5% to 15% of the height H0 of the core 2.

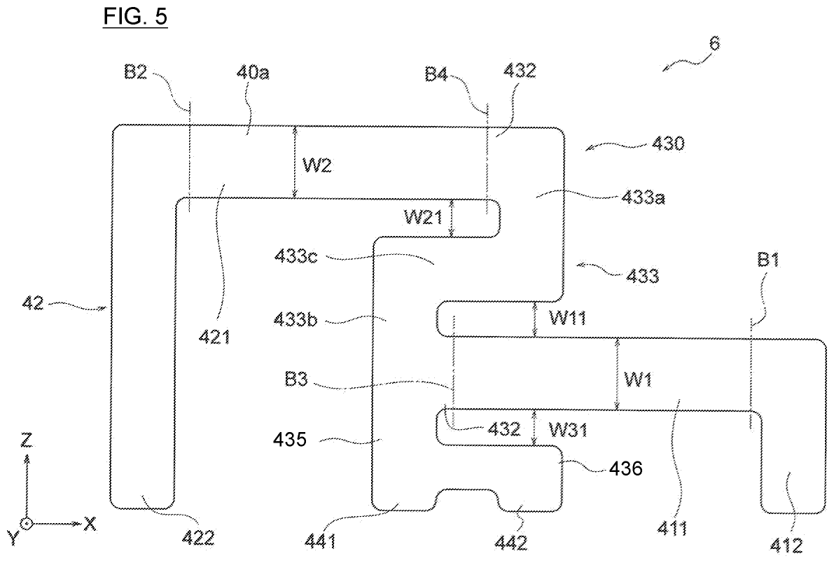

The coil 40 can be formed by, for example, folding one metal plate member 6 having a shape shown in FIG. 5 as follows. In FIG. 5, the metal plate member 6 is disposed so that its main surface 40a faces the near side in the Y-axis direction (i.e., the front side of FIG. 5) and its main surface 40b faces the far side in the Y-axis direction (i.e., the back side of FIG. 5).

To form the metal plate member 6 into the coil 40, first, while the metal plate member 6 is in the state shown in FIG. 5, the first terminal portion 412 is folded to the near side (i.e., to the near side of FIG. 5) at a fold line B1 at right angles with respect to the first main portion 411 so that the main surface 40a of the first terminal portion 412 faces the first main portion 411. Then, at a fold line B2, the second terminal portion 422 is folded to the near side (i.e., to the near side of FIG. 5) at right angles with respect to the second main portion 421 so that the main surface 40a of the second terminal portion 422 faces the second main portion 421.

Then, at a fold line B3, the first main portion 411 is folded to the far side (i.e., to the deep side of FIG. 5) at right angles with respect to the connecting portion 433. The metal plate member 6 being folded in such a manner, the main surface 40a of the first terminal portion 412 faces the near side. Then, at a fold line B4, the second main portion 421 is folded to the far side (i.e., to the deep side of FIG. 5) at right angles with respect to the connecting portion 433. The metal plate member 6 being folded in such a manner, the main surface 40a of the second terminal portion 422 faces the near side.

As illustrated in FIG. 5, the metal plate member 6 has the first space having the predetermined width W11 between the middle portion 433c and the first main portion 411. Likewise, the metal plate member 6 has the second space having the predetermined width W21 between the middle portion 433c and the second main portion 421. Further, the metal plate member 6 has the third space having the predetermined width W31 between the first main portion 411 and the reinforcing portion 436. The widths W11, W21, and W31 are not smaller than the thickness T between the main surfaces 40a and 40b illustrated in FIG. 4. Such a structure makes it easy to fold the metal plate member 6 into the coil 40. Forming the coil 40 by folding one metal plate member 6 eliminates a need for joining parts by welding or the like, reduces work complexity, and enables manufacture of the coil 40 having high strength.

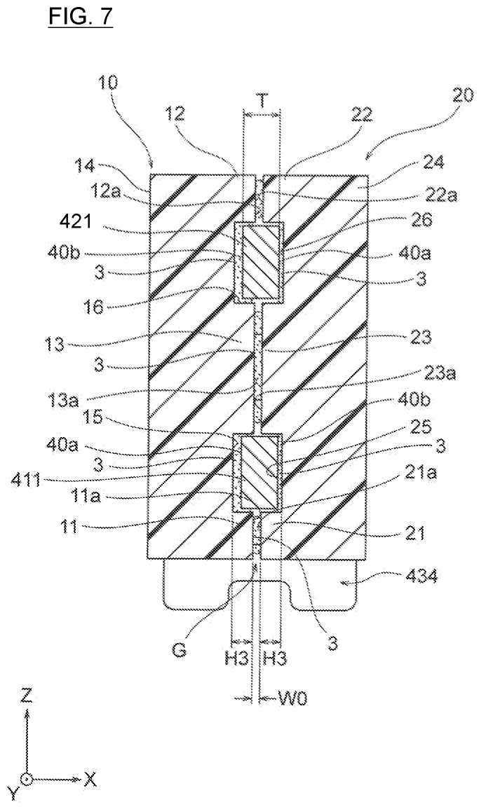

FIG. 7 is a sectional view of the coil device 1. As illustrated in FIG. 7, the first section 10 is disposed to oppose the second section 20 in the X-axis direction. Respective end surfaces 11a, 12a, and 13a of the leg portions 11, 12, and 13 of the first section 10 oppose respective end surfaces 21a, 22a, and 23a of the leg portions 21, 22, and 23 of the second section 20. The end surfaces 11a, 12a, and 13a are anchored to the end surfaces 21a, 22a, and 23a respectively using the adhesive member 3. Between the end surfaces 11a, 12a, and 13a and the end surfaces 21a, 22a, and 23a is a gap G having a width W0. The width W0 of the gap G is not limited and can be, for example, 300 μm or less. It may be that the adhesive member 3 is not disposed on the end surfaces of the leg portions in their entirety. Further, it may be that the end surfaces are in direct contact with each other not to have the gap G.

As illustrated in FIG. 7, the first main portion 411 and the second main portion 421 are interposed between the first section 10 and the second section 20. The first main portion 411 is disposed in a space provided by the first recess 15 of the first section 10 and the first recess 25 of the second section 20. The main surface 40a of the first main portion 411 is disposed to oppose a bottom surface of the first recess 15 of the first section 10 and is anchored thereto using the adhesive member 3. The main surface 40b of the first main portion 411 is disposed to oppose a bottom surface of the first recess 25 of the second section 20 and is anchored thereto using the adhesive member 3.

The second main portion 421 is disposed in a space provided by the second recess 16 of the first section 10 and the second recess 26 of the second section 20. The main surface 40b of the second main portion 421 is disposed to oppose a bottom surface of the second recess 16 of the first section 10 and is anchored thereto using the adhesive member 3. The main surface 40a of the second main portion 421 is disposed to oppose a bottom surface of the second recess 26 of the second section 20 and is anchored thereto using the adhesive member 3.

As illustrated in FIG. 7, a height H3 of the leg portions 11, 12, and 13 protruding from the base portion 14 in the X-axis direction is smaller than the thickness T of the first main portion 411 and the second main portion 421. The gap G is located between the main surfaces 40a and 40b of the first main portion 411 and the second main portion 421 along the X-axis direction.

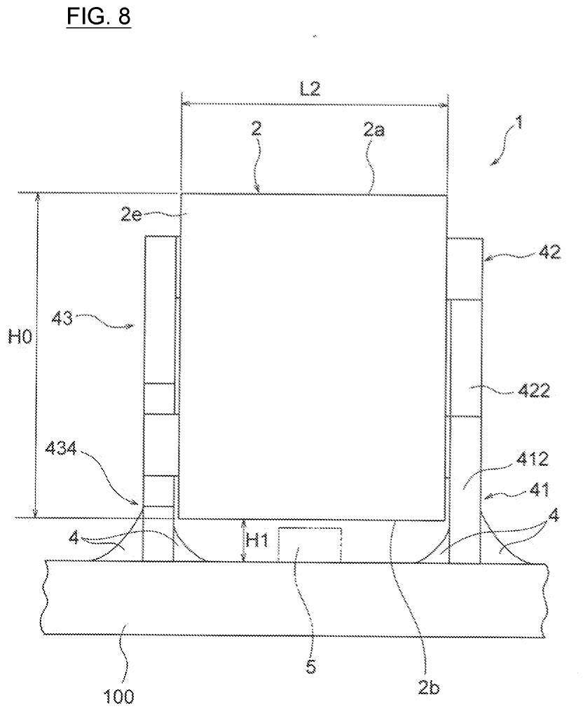

FIG. 8 illustrates an example of the coil device 1 mounted on a circuit board 100 (e.g., PCB). As illustrated in FIG. 8, the coil device 1 can be mounted on the circuit board 100 by anchoring the first terminal portion 412, the second terminal portion 422, and the locating portion 434 to the circuit board 100 using, for example, solder 4. When the coil device 1 is mounted on the circuit board 100 or the like in such a manner, the thickness T of the coil 40 is as thick as to have a strength that enables support of the coil device 1. The first terminal portion 412, the second terminal portion 422, and the locating portion 434 may be folded in the Y-axis direction to form mounting pieces. When the first terminal portion 412 and the second terminal portion 422 are provided with the mounting pieces, the thickness T of the coil 40 May be thinned as necessary. When the mounting pieces are provided, the coil device 1 can more stably be mounted on the circuit board 100 or the like.

Mounting methods for the coil device 1 are not limited to soldering. For example, the coil device 1 may be mounted on the circuit board 100 by pressure-bonding or by inserting the first terminal portion 412, the second terminal portion 422, and the locating portion 434 into holes provided on the circuit board 100.

As illustrated in FIG. 8, the coil device 1 has a raised bottom structure, in which the bottom surface 2b of the core 2 is at a level that is higher by the height H1 from the circuit board 100. Thus, when the coil device 1 is mounted on the circuit board 100, a space for mounting an other electronic device 5 or the like is provided between the bottom surface 2b of the core 2 and the circuit board 100. In a product including the coil device 1, as the other electronic device 5 is mounted in such a manner on the same mounting surface where the coil device 1 is mounted, the product can be downsized in its entirety.

As illustrated in FIG. 1, in the coil device 1, the first main portion 411 is disposed so as to overlap the second main portion 421, viewed from the Z-axis direction, which is perpendicular to the bottom surface 2b. Thus, the bottom surface 2b of the core 2 can have a smaller area. The coil device 1 can be mounted on the circuit board or the like of the product, with the bottom surface 2b having the small area facing the circuit board or the like. Thus, the mounting area can be reduced, which can downsize the product. Note that, although the first main portion 411 and the second main portion 421 do not necessarily have to overlap in their entirety, disposing them at an overlapping location enables reduction of the mounting area while inductance is ensured.

The coil 40 is formed from one metal plate member 6, which can be molded to ensure having desired inductance, and failure risks can be reduced. Such a coil device 1 is applicable for use involving a large current.

As illustrated in FIG. 1, the first terminal portion 412 and the second terminal portion 422 are disposed over the outer surface 2c of the core 2, and the locating portion 434 is disposed over the outer surface 2d of the core 2. Such a structure ensures that one turn of winding having the middle leg portions of the core 2 as an axis is provided for the coil device 1 with one of the first terminal portion 412 and the second terminal portion 422 as an input side and the other as an output side. Further, as the first terminal portion 412 and the second terminal portion 422 are disposed at one side of the coil device 1 in the Y-axis direction and the locating portion 434 is disposed at the other side of the coil device 1 in the Y-axis direction, the coil device 1 can be stably mounted on the circuit board.

In the present embodiment, the first terminal portion 412 is disposed over the outer surface 2c of the first section 10. The second terminal portion 422 is disposed over the outer surface 2c of the second section 20 and next to the first terminal portion 412. Such a structure enables the coil device 1 to have increased inductance. To adjust the inductance, the width W1 of the first main portion 411 may be different from the width W2 of the second main portion 421.

In the present embodiment, as illustrated in FIG. 6, the first section 10 includes the base portion 14, which has the substantially flat shape, and the leg portions 11, 12, and 13, which protrude from the base portion 14 towards the second section 20. The respective end surfaces 11a, 12a, and 13a of the leg portions 11, 12, and 13 are disposed so that the gap having the predetermined width W0 is provided between the end surfaces and the second section 20. As the gap having the predetermined width W0 is provided in such a manner, leakage from the coil device 1 can be adjusted.

In the present embodiment, the first section 10 is connected to the second section 20 using the adhesive member 3 at the end surfaces 11a, 12a, and 13a. In this manner, the core 2 can be easily molded by connecting the individually molded first section 10 and second section 20 using the adhesive member 3. With the adhesive member 3, the predetermined width W0 of the gap between the sections can be adjusted.

### Second Embodiment

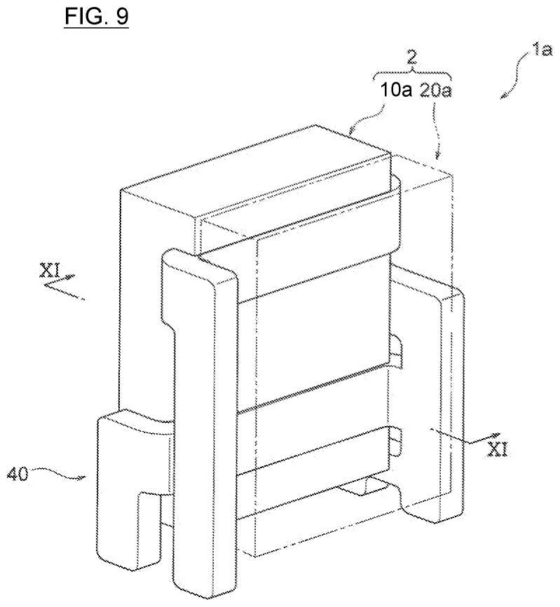

A coil device 1a according to the present embodiment illustrated in FIG. 9 is different from the first embodiment in that only the shape of a core 2 is different therefrom.

Description common to the first and second embodiments is omitted, and mainly what is different from the first embodiment is described below in detail. What is not described in the following description is similar to the first embodiment.

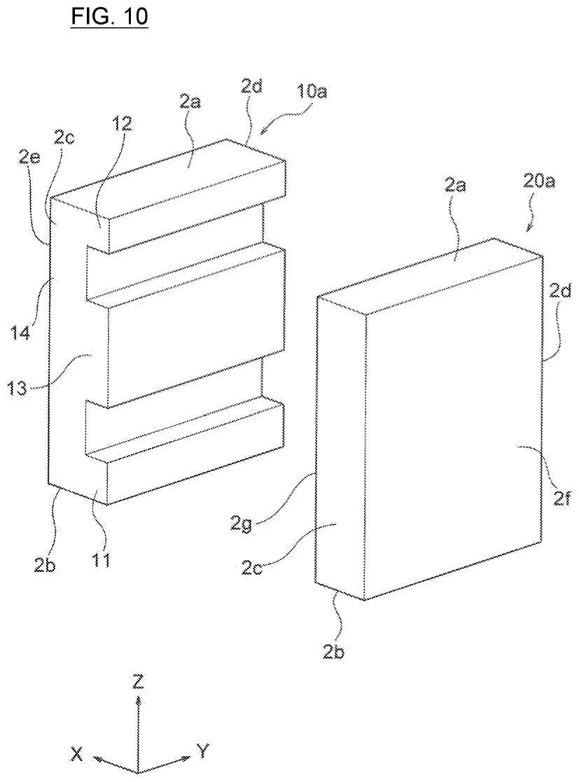

As illustrated in FIG. 10, the core 2 includes a combination of a first section 10a and a second section 20a. The first section 10a has a so-called E-shape, and the second section 20a has a so-called I shape having an inner surface 2g substantially parallel to a base surface 2f.

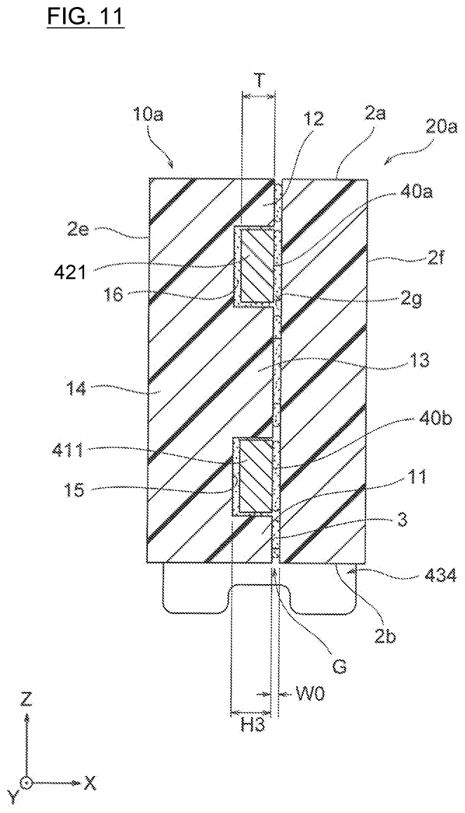

As illustrated in FIG. 11, the first section 10a includes leg portions 11, 12, and 13 protruding from a base portion 14 in the X-axis direction. A protruding height H3 of the leg portions 11, 12, and 13 is larger than the thickness T of a first main portion 411 and a second main portion 421.

A main surface 40a of the first main portion 411 is disposed to oppose a bottom surface of a first recess 15 of the first section 10a and is anchored thereto using an adhesive member 3. A main surface 40b of the first main portion 411 is anchored to the inner surface 2g of the second section 20a using the adhesive member 3.

The main surface 40b of the second main portion 421 is disposed to oppose a bottom surface of a second recess 16 of the first section 10a and is anchored thereto using the adhesive member 3. The main surface 40a of the second main portion 421 is anchored to the inner surface 2g of the second section 20a using the adhesive member 3.

Between the inner surface 2g of the second section 20a and the leg portions 11, 12, and 13 is a gap G having a predetermined width W0. The gap G is located closer to the second section 20a than the main surface 40b of the first main portion 411 and the main surface 40a of the second main portion 421 along the X-axis direction.

Such a structure enables the gap not to be disposed at lateral sides of the first main portion 411 and the second main portion 421 to more efficiently adjust leakage.

### Third Embodiment

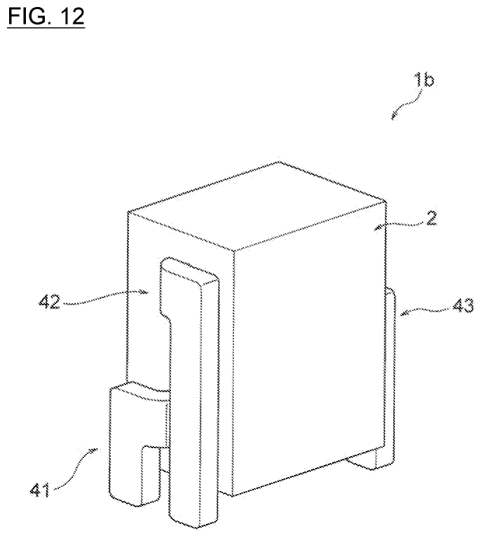

A coil device 1b according to the present embodiment illustrated in FIG. 12 is different from the first embodiment in that only the structure of a core 2 is different therefrom. Description common to the first and third embodiments is omitted, and mainly what is different from the first embodiment is described below in detail. What is not described in the following description is similar to the first embodiment.

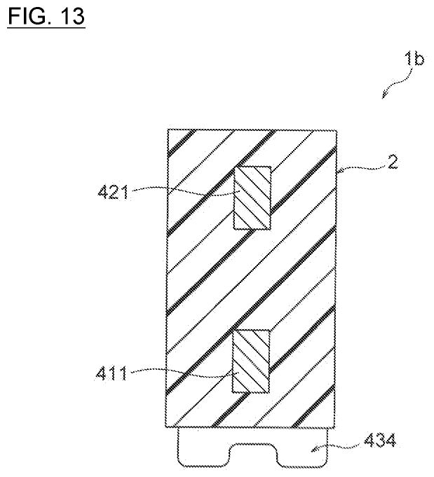

FIG. 13 is a sectional view of the coil device 1b. In the present embodiment, the core 2 is composed of a molding material containing magnetic material and resin material.

Examples of magnetic material contained in the molding material are not limited and may include ferrites and metal magnetic material. Examples of ferrites are not limited and include Ni—Zn based ferrites and Mn—Zn based ferrites. Examples of metal magnetic material are not limited and include Fe—Ni alloys, Fe—Si alloys, Fe—Si—Cr alloys, Fe—Co alloys, and Fe—Si—Al alloys. Examples of resin material contained in the molding material are not limited and include epoxy resin, phenol resin, polyester resin, polyurethane resin, polyimide resin, other synthetic resin, and other non-magnetic material.

In manufacture of the coil device 1b of the present embodiment, the following method may be used. The molding material containing the magnetic material and the resin material, a mold for molding the core 2, and the coil 40 illustrated in FIG. 4 are prepared. Filling the mold with the molding material, and molding the core 2 by disposing the coil 40 at a predetermined location and compressing the molding material using a known method give the coil device 1b. Note that, for molding of the core 2, injection molding or the like may be used.

As illustrated in FIG. 13, it may be that an adhesive member or the like is not used in the coil device 1b. Also, it may be that the core 2 is not divided into sections to have no gap between the sections.

Variously modified forms, shapes, etc. within the scope of the claims are included in the technical scopes of the above-mentioned embodiments.

### REFERENCE NUMERALS

1, 1a, 1b . . . coil device
2 . . . core
2a . . . top surface
2b . . . bottom surface
2c, 2d . . . outer surface
2e, 2f . . . base surface
2g . . . inner surface
10, 10a . . . first section
11 . . . first outer leg portion
11a . . . end surface
12 . . . second outer leg portion
12a . . . end surface
13 . . . middle leg portion
13a . . . end surface
14 . . . base portion
15 . . . first recess
16 . . . second recess
20, 20a . . . second section
21 . . . first outer leg portion
21a . . . end surface
22 . . . second outer leg portion
22a . . . end surface
23 . . . middle leg portion
23a . . . end surface
24 . . . base portion
25 . . . first recess
26 . . . second recess
40 . . . coil
40a, 40b . . . main surface
41 . . . first conductor
411 . . . first main portion
412 . . . first terminal portion
42 . . . second conductor
421 . . . second main portion
422 . . . second terminal portion
43 . . . third conductor
430 . . . joint portion
431 . . . first connecting end portion
432 . . . second connecting end portion
433 . . . connecting portion
433a . . . first portion
433b . . . second portion
433c . . . middle portion
434 . . . locating portion
435 . . . supporting portion
436 . . . reinforcing portion
441, 442 . . . protrusion
3 . . . adhesive member
4 . . . solder
5 . . . electronic device
6 . . . metal plate member
100 . . . circuit board

What is claimed is:

1. A coil device comprising:
a core; and
a coil including a folded metal plate member having a pair of main surfaces extending in a direction perpendicular to a bottom surface of the core;
wherein
the coil includes a first conductor, a second conductor, and a third conductor;
the first conductor includes a first main portion and a first terminal portion;
the first main portion is disposed inside the core;
the first terminal portion is connected to the first main portion and partly protrudes below the bottom surface;
the second conductor includes a second main portion and a second terminal portion;
the second main portion is disposed inside the core and farther from the bottom surface than the first main portion;
the second terminal portion is connected to the second main portion and partly protrudes below the bottom surface;
the third conductor includes a joint portion and a locating portion;
the joint portion connects the first conductor and the second conductor; and
the locating portion partly protrudes below the bottom surface.

2. The coil device according to claim 1, wherein the first main portion is disposed so as to at least partly overlap the second main portion, viewed from the direction perpendicular to the bottom surface.

3. The coil device according to claim 1, wherein
the first terminal portion and the second terminal portion are disposed over an outer surface of the core at one side; and
the locating portion is disposed over the outer surface of the core at an other side.

4. The coil device according to claim 1, wherein
the joint portion comprises a first connecting end portion having at least one of the main surfaces being curved from the first main portion to run along an outer surface of the core, a second connecting end portion having at least one of the main surfaces being curved from the second main portion to run along the outer surface, and a connecting portion connecting the first connecting end portion and the second connecting end portion;
the connecting portion comprises a middle portion extending in a direction parallel to the bottom surface of the core;
the connecting portion has a first space between the middle portion and the first connecting end portion and a second space between the middle portion and the second connecting end portion; and
the first space and the second space have a width not smaller than a thickness of the coil.

5. The coil device according to claim 1, wherein
the core comprises a first section and a second section opposing each other in a direction parallel to the bottom surface of the core; and
the first main portion and the second main portion are interposed between the first section and the second section.

6. The coil device according to claim 5, wherein
the first section comprises a base portion having a substantially flat shape and a leg portion protruding from the base portion towards the second section; and
an end surface of the leg portion is disposed so that a gap is provided between the end surface and the second section.

7. The coil device according to claim 5, wherein the first section is connected to the second section using an adhesive member.

8. The coil device according to claim 5, wherein a length of the leg portion protruding from the base portion is larger than a thickness of the coil in the direction parallel to the bottom surface.

9. The coil device according to claim 5, wherein
the first terminal portion is disposed over an outer surface of the first section at one side; and
the second terminal portion is disposed over an outer surface of the second section at the one side and next to the first terminal portion.

10. The coil device according to claim 1, wherein the first main portion and the second main portion have different widths.
